(19) United States
(12) Patent Application Publication
(10) Pub. No.: US 2026/0129312 A1
(43) Pub. Date: May 7, 2026

(54) IMAGE SENSING DEVICE

(71) Applicant: SK hynix Inc., Icheon-si (KR)

(72) Inventors: Sung Ho CHOI, Icheon-si (KR); Hee Dong KIM, Icheon-si (KR); Hyeon Jeong LEE, Icheon-si (KR); Hyun Soo LIM, Icheon-si (KR); Hyo Jun KWON, Icheon-si (KR); Da Yea BAEK, Icheon-si (KR)

(21) Appl. No.: 19/288,866

(22) Filed: Aug. 1, 2025

(30) Foreign Application Priority Data
Nov. 1, 2024 (KR) 10-2024-0153645

(51) Int. Cl. H04N 25/51; H04N 25/77

(52) U.S. Cl. CPC H04N 25/51; H04N 25/77

(57) ABSTRACT

Image sensing devices capable of implementing multiple gains are disclosed. In an embodiment, an image sensing device includes a first pixel including first and second dual conversion gain (DCG) transistors that adjust capacitance of a first floating diffusion region shared by a plurality of pixels included in a first pixel group; and a second pixel including third and fourth DCG transistors that adjust capacitance of a second floating diffusion region shared by a plurality of pixels included in a second pixel group arranged at one side of the first pixel group. A gate of the first DCG transistor and a gate of the second DCG transistor are arranged closer to the second pixel from a center of the first pixel, and a gate of the third DCG transistor and a gate of the fourth DCG transistor are arranged closer to the first pixel from a center of the second pixel.

### CROSS-REFERENCE TO RELATED APPLICATION

This patent document claims the priority and benefits of Korean patent application No. 10-2024-0153645, filed on Nov. 1, 2024, the disclosure of which is incorporated herein by reference in its entirety as part of the disclosure of this patent document.

### TECHNICAL FIELD

The technology and embodiments disclosed in this patent document generally relate to an image sensing device, and more particularly to an image sensing device capable of implementing multiple gains.

### BACKGROUND

An image sensing device can capture optical images by converting light into electrical signals using a photosensitive semiconductor material that reacts to light. With advancements in industries such as automotive, medical, computer and communication industries, the demand for high-performance image sensing devices is growing across various fields, such as smartphones, digital cameras, game machines, IoT (Internet of Things), robots, security cameras and medical micro cameras.

The image sensing device may be roughly divided charge coupled device (CCD) image sensing devices and complementary metal oxide semiconductor (CMOS) image sensing devices. CCD image sensing devices offer a better image quality, but they tend to consume more power and are larger as compared to CMOS image sensing devices. CMOS image sensing devices are smaller in size and consume less power than CCD image sensing devices. Furthermore, CMOS image sensing devices are fabricated using the CMOS fabrication technology, and thus photosensitive elements and other signal processing circuitry can be integrated into a single chip, enabling the production of miniaturized image sensing devices at a lower cost. For these reasons, CMOS image sensing devices are being developed for many applications including mobile devices.

### SUMMARY

Various embodiments of the disclosed technology relate to an image sensing device capable of reducing junction capacitance and implementing multiple conversion gains when two different dual conversion gain (DCG) transistors are electrically connected to each other.

Various embodiments of the disclosed technology relate to an image sensing device capable of more precisely adjusting the ratio of multiple conversion gains.

In an embodiment of the disclosed technology, an image sensing device may include a pixel array of pixels for sensing incident light to capture images carried by the incident light, wherein the pixel array includes a first pixel group of pixels and a second pixel group of pixels arranged at one side of and adjacent to the first pixel group, wherein the first pixel group includes a first pixel including first and second dual conversion gain (DCG) transistors configured to adjust a capacitance of a first floating diffusion region shared by a plurality of pixels included in the first pixel group, and wherein the second pixel group includes a second pixel including third and fourth DCG transistors configured to adjust a capacitance of a second floating diffusion region shared by a plurality of pixels included in the second pixel group, wherein a gate of the first DCG transistor and a gate of the second DCG transistor are arranged such that a distance between the gates of the first and second DCG transistors and the second pixel is shorter than a distance between the second pixel and a center of the first pixel, and a gate of the third DCG transistor and a gate of the fourth DCG transistor are arranged such that a distance between the gates of the third and fourth DCG transistors and the first pixel is shorter than a distance between the first pixel and a center of the second pixel.

In some implementations, the image sensing device may further include: a first dual conversion gain (DCG) electrical interconnect line configured to electrically connect a terminal of the first DCG transistor to a terminal of the third DCG transistor; and a second DCG electrical interconnect line configured to electrically connect a terminal of the second DCG transistor to a terminal of the fourth DCG transistor.

In some implementations, the first pixel may include first and second photoelectric conversion elements configured to generate photocharges in response to incident light, and the second pixel includes: third and fourth photoelectric conversion elements configured to generate photocharges in response to the incident light.

In some implementations, the image sensing device may further include: a pixel isolation structure disposed between the first and second photoelectric conversion elements and between the third and fourth photoelectric conversion elements.

In some implementations, the gate of the first DCG transistor may overlap the first photoelectric conversion element; the gate of the second DCG transistor may overlap the second photoelectric conversion element; the gate of the third DCG transistor may overlap the third photoelectric conversion element; and the gate of the fourth DCG transistor may overlap the fourth photoelectric conversion element.

In some implementations, the first pixel may further include: a first transfer transistor configured to move the photocharges generated by the first photoelectric conversion element to the first floating diffusion region; and a second transfer transistor configured to move the photocharges generated by the second photoelectric conversion element to the first floating diffusion region. The second pixel may further include: a third transfer transistor configured to move the photocharges generated by the third photoelectric conversion element to the second floating diffusion region; and a fourth transfer transistor configured to move the photocharges generated by the fourth photoelectric conversion element to the second floating diffusion region.

In some implementations, the first pixel group may further include a first drive transistor configured to amplify an electrical signal corresponding to photocharges stored in the first floating diffusion region. The second pixel group may further include a second drive transistor configured to amplify an electrical signal corresponding to photocharges stored in the second floating diffusion region.

In some implementations, the first pixel group may further include a first selection transistor configured to selectively output an electrical signal amplified by the first drive transistor. The second pixel group may further include a second selection transistor configured to selectively output an electrical signal amplified by the second drive transistor.

In some implementations, the first pixel group may include a first reset transistor configured to reset the first floating diffusion region, and the second pixel group may include a second reset transistor configured to reset the second floating diffusion region.

In some implementations, the image sensing device may further include: a third dual conversion gain (DCG) electrical interconnect line configured to electrically connect a terminal of the first DCG transistor to a terminal of the second DCG transistor; and a fourth DCG electrical interconnect line configured to electrically connect a terminal of the third DCG transistor to a terminal of the fourth DCG transistor.

In some implementations, the first floating diffusion region may be electrically connected to a terminal of the first DCG transistor; and the second floating diffusion region may be electrically connected to a terminal of the third DCG transistor.

In another embodiment of the disclosed technology, an image sensing device may include: a first pixel including first and second photoelectric conversion elements configured to generate photocharges in response to incident light; a second pixel including third and fourth photoelectric conversion elements configured to generate photocharges in response to the incident light, the second pixel being in contact with a side surface of the first pixel; a third pixel including fifth and sixth photoelectric conversion elements configured to generate photocharges in response to the incident light, a side surface of the third pixel being in contact with an opposite side surface of the first pixel; and a fourth pixel including seventh and eighth photoelectric conversion elements configured to generate photocharges in response to the incident light, the fourth pixel being in contact with an opposite side surface of the third pixel. The first pixel may include: first and second dual conversion gain (DCG) transistors configured to adjust conversion gains of the first and second pixels and are arranged such that a distance between the first and second DCG transistors and the side surface of the third pixel is shorter than a distance between the first and second DCG transistors and the side surface of the first pixel. The third pixel may include: third and fourth DCG transistors configured to adjust conversion gains of the third and fourth pixels and are arranged such that a distance between the third and fourth DCG transistors and the opposite side surface of the first pixel is shorter than a distance between the third and fourth DCG transistors and the opposite side surface of the third pixel.

In some implementations, one terminal of the first DCG transistor and one terminal of the third DCG transistor may be electrically connected to each other; and one terminal of the second DCG transistor and one terminal of the fourth DCG transistor may be electrically connected to each other.

In some implementations, the first pixel may include: a first floating diffusion region configured to store photocharges generated by the first photoelectric conversion element and the second photoelectric conversion element. The second pixel may include: a second floating diffusion region configured to store photocharges generated by the third photoelectric conversion element and the fourth photoelectric conversion element.

In some implementations, another terminal of the first DCG transistor may be electrically connected to the first floating diffusion region; and another terminal of the third DCG transistor may be electrically connected to the second floating diffusion region.

In some implementations, one terminal of the first DCG transistor may be electrically connected to another terminal of the second DCG transistor; and one terminal of the third DCG transistor may be electrically connected to another terminal of the fourth DCG transistor.

In some implementations, when all of the first to fourth DCG transistors are turned off, the first and second pixels have a high conversion gain higher than a middle conversion gain; when the first DCG transistor is turned on and the second to fourth DCG transistors are turned off, the first pixel and the second pixel have the middle conversion gain higher than a low conversion gain and lower than the high conversion gain; and when all of the first to fourth DCG transistors are turned on, the first pixel and the second pixel have the low conversion gain lower than the high conversion gain and the middle conversion gain.

In some implementations, the middle conversion gain may be twice the low conversion gain.

In some implementations, the high conversion gain may be eight times the low conversion gain.

In some implementations, when all of the first to fourth DCG transistors are turned off, the third and fourth pixels have a high conversion gain higher than a middle conversion gain; when the third DCG transistor is turned on and the first, second, and fourth DCG transistors are turned off, the third and fourth pixels have the middle conversion gain higher than a low conversion gain and lower than the high conversion gain; and when all of the first to fourth DCG transistors are turned on, the third and fourth pixels have the low conversion gain lower than the high conversion gain and the middle conversion gain.

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

The above and other features and beneficial aspects of the disclosed technology will become readily apparent with reference to the following detailed description when considered in conjunction with the accompanying drawings.

FIG. 1 is a block diagram illustrating an example of an image sensing device based on some embodiments of the disclosed technology.

FIG. 2 is a plan view illustrating an example of a pixel array of the image sensing device shown in FIG. 1 based on some embodiments of the disclosed technology.

FIG. 3 is a circuit diagram illustrating an example of a first pixel region or a second pixel region shown in FIG. 2 based on some embodiments of the disclosed technology.

FIG. 4 is a plan view illustrating an example of the first pixel region shown in FIG. 2 based on some embodiments of the disclosed technology.

FIG. 5A is a cross-sectional view illustrating an example of the structure taken along the line A-A′ shown in FIG. 4 based on some embodiments of the disclosed technology.

FIG. 5B is a cross-sectional view illustrating an example of the structure taken along the line B-B′ shown in FIG. 4 based on some embodiments of the disclosed technology.

FIG. 5C is a cross-sectional view illustrating an example of the structure taken along the line C-C′ shown in FIG. 4 based on some embodiments of the disclosed technology.

FIG. 6 is a plan view illustrating another example of the second pixel region shown in FIG. 2 based on some embodiments of the disclosed technology.

### DETAILED DESCRIPTION

This patent document provides embodiments and examples of an image sensing device capable of implementing multiple gains that may be used in configurations to substantially address one or more technical or engineering issues and to mitigate limitations or disadvantages encountered in some image sensing devices in the art. Some embodiments of the disclosed technology relate to an image sensing device that can reduce junction capacitance and implementing multiple conversion gains when two different dual conversion gain (DCG) transistors are electrically connected to each other. Some embodiments of the disclosed technology relate to an image sensing device that can more precisely adjust the ratio of multiple conversion gains. In recognition of the issues above, the image sensing device based on some embodiments of the disclosed technology may implement a higher conversion gain by reducing junction capacitance and may have a more precisely designed conversion gain ratio. In some embodiments, the term “dual conversion gain transistor” refers to a type of transistor within a pixel on a CMOS image sensing device that allows for two different amplification levels (or conversion gains) to be applied to the captured photocharge. Dual conversion gain (DCG) can improve the dynamic range of an image sensor by adjusting the conversion gain based on the amount of light. The disclosed technology can be implemented in some embodiments to be applied not only to configurations using dual conversion gain transistors, but also to those using transistors with three or more conversion gains, such as triple conversion gain transistors.

Reference will now be made in detail to the embodiments of the disclosed technology, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, it should be understood that the disclosed technology is not limited to specific embodiments, but includes various modifications, equivalents and/or alternatives of the embodiments. The embodiments of the disclosed technology may provide a variety of effects capable of being directly or indirectly recognized through the disclosed technology.

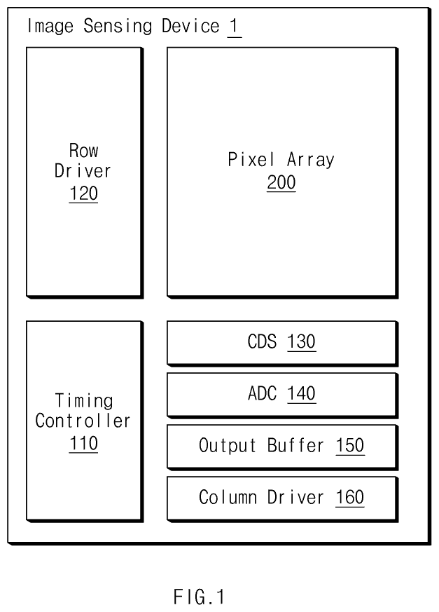

FIG. 1 is a block diagram illustrating an example of an image sensing device 1 based on some embodiments of the disclosed technology.

Referring to FIG. 1, an image sensing device 1 based on an embodiment of the disclosed technology may include a timing controller 110, a row driver 120, a pixel array 200, a correlated double sampler (CDS) 130, an analog-to-digital converter (ADC) 140, an output buffer 150, and a column driver 160. The components of the image sensing device illustrated in FIG. 1 are discussed by way of example only, and this patent document encompasses numerous other changes, substitutions, variations, alterations, and modifications. In this patent document, the word “pixel” can be used to indicate an image sensing pixel that is structured to detect incident light to generate electrical signals carrying images in the incident light.

The timing controller 110 may provide timing signals and control signals to at least one of the row driver 120, the correlated double sampler (CDS) 130, the ADC 140, the output buffer 150, and the column driver 160.

The row driver 120 may activate the pixel array 200 to perform specific operations on pixels included in a corresponding row based on the timing and control signals received from the timing controller 110.

In some implementations, the row driver 120 may select at least one pixel arranged in at least one row of the pixel array 200, and may provide the selected pixel with a control signal for performing a specific operation. The row driver 120 may generate a row selection signal to select at least one row from among a plurality of rows. When the row driver 120 selects a specific row from among the plurality of rows to perform a specific operation, the row driver 120 may not perform the specific operation on a row adjacent to the selected specific row.

The pixels of the row selected by the row driver 120 may sequentially transfer analog reference signals and image signals to the correlated double sampler (CDS) 130. The reference signal may be an electrical signal provided to the CDS 130 when a floating diffusion region of each pixel is reset to a power-supply voltage VDD. The image signal may be an electrical signal provided to the CDS 130 when photocharges generated by each pixel are accumulated in the floating diffusion (FD) region.

The reference signal may be a signal indicating unique pixel noise of each pixel, and the reference signal and the image signal may be collectively referred to as a pixel signal as necessary.

The pixel array 200 may include a plurality of pixels arranged in a plurality of rows and a plurality of columns. The plurality of pixels may be connected to the row driver 120 through a plurality of row lines extending in the row direction. The plurality of pixels may be connected to the CDS 130 through a plurality of column lines extending in the column direction. The pixel array 200 may include at least one pixel PX arranged in the row direction and the column direction. For example, the pixel array 200 may be arranged in a two-dimensional (2D) pixel array of a plurality of unit pixels including rows and columns.

The plurality of unit pixels included in the pixel array 200 may convert optical signals into electrical signals, and may be connected to a specific internal pixel circuit.

The pixel array 200 may receive pixel control signals including a row selection signal, a pixel reset signal, a row transfer signal, etc. from the row driver 120. At least one pixel included in the row that is selected by the row driver 120 according to the pixel control signal may perform a specific operation in response to the row selection signal, the pixel reset signal, and the row transfer signal.

The CDS 130 may receive the reference signal and the image signal, each of which corresponds to the columns of the pixel array 200, and may sample levels of the reference signal and the image signal. In the image sensing device designed to use CMOS(s), the CDS 130 may sample a pixel signal twice to remove a difference between these two samples, and may perform correlated double sampling to remove undesired offset values of pixels such as fixed noise. For example, the CDS 130 may compare pixel output voltages obtained before and after photocharges generated by incident light are accumulated in the floating diffusion region to remove undesired offset values, so that the pixel output voltages based on the incident light can be measured.

The CDS 130 may transmit reference signals and image signals, which are generated in columns based on a timing signal and a control signal of the timing controller 110, to the ADC 140 as CDS signals.

The ADC 140 may convert analog CDS signals received from the CDS 130 into digital signals, and may output the resultant digital signals.

The output buffer 150 may temporarily hold and output digital signals provided from the ADC 140.

The column driver 160 may select columns from the output buffer 150 based on a timing signal and a control signal of the timing controller 110, and may control the temporarily held digital signals to be output according to the selection order.

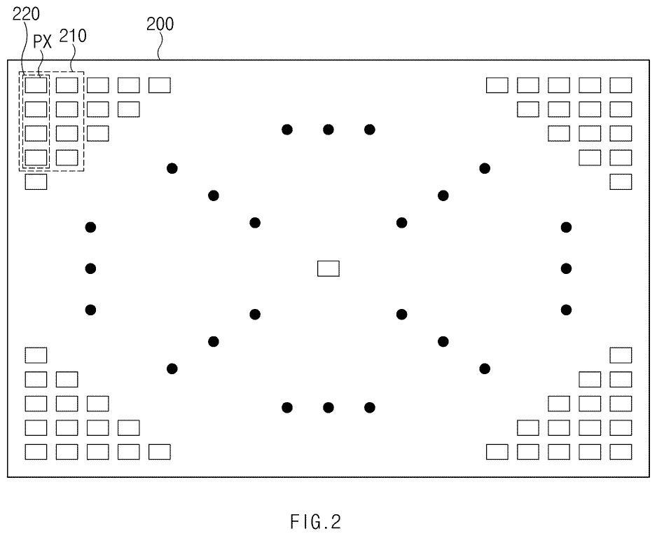

FIG. 2 is a plan view illustrating an example of the pixel array 200 of the image sensing device 1 shown in FIG. 1 based on some embodiments of the disclosed technology.

Referring to FIGS. 1 and 2, the pixel array 200 may include, for example, a structure in which a plurality of pixels (PXs) is arranged in a two-dimensional (2D) matrix structure. The pixel array 200 may include M pixels (PXs) arranged in a horizontal direction (where M is an integer greater than or equal to 2). The pixel array 200 may include N pixels (PXs) arranged in a vertical direction (where N is an integer greater than or equal to 2).

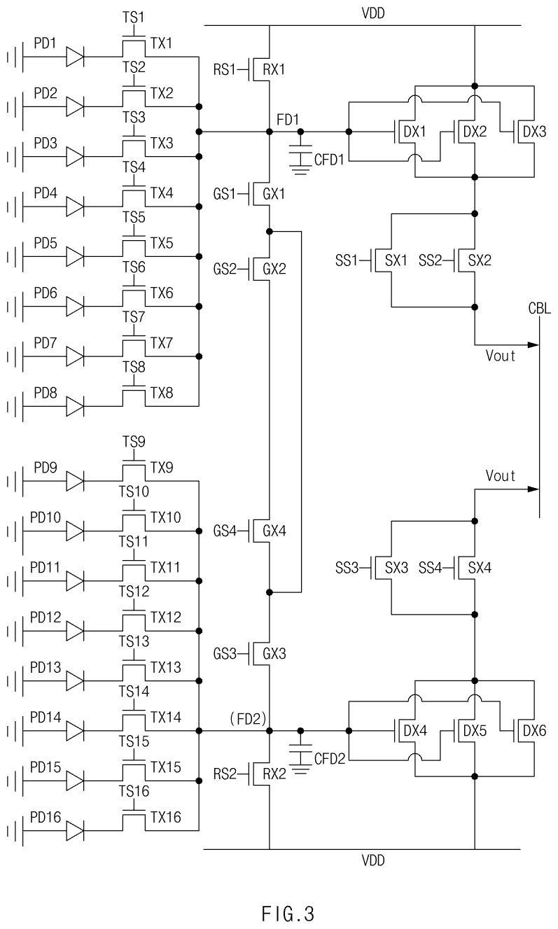

The pixel array 200 may include a first pixel region 210 and a second pixel region 220. The first pixel region 210 may be a region in which eight pixels (PXs) are arranged in a (2×4) matrix structure. The second pixel region 220 may be a region in which four pixels are arranged in a (1×4) matrix structure. Although FIG. 2 shows that each of the first pixel region 210 and the second pixel region 220 is illustrated as a region located at an edge of the pixel array 200 for convenience of description, the disclosed technology is not limited thereto, it should be noted that any eight pixels (PXs) arranged in a (2×4) matrix structure in the pixel array 200 may correspond to the first pixel region 210 and any four pixels (PXs) arranged in a (1×4) matrix structure may correspond to the second pixel region 220. To enhance clarity, FIG. 2 depicts the plurality of pixels (PXs), which can be part of the first pixel region 210 and/or the second pixel region 220, as being spaced apart from each other. However, the plurality of pixels (PXs) may also be arranged to be in contact with each other. In some embodiments, the first pixel region 210 or the second pixel region 220 can be configured as will be discussed below with reference to the drawings below such as FIG. 3.

FIG. 3 is a circuit diagram illustrating an example model of the first pixel region 210 or the second pixel region 220 shown in FIG. 2 based on some embodiments of the disclosed technology.

Referring to FIG. 3, the circuit diagram of FIG. 3 may include first to sixteenth photoelectric conversion elements (PD1-PD16), first to sixteenth transfer transistors (TX1-TX16), first and second reset transistors (RX1, RX2), first and second floating diffusion nodes (FD1, FD2), first to sixth drive transistors (DX1-DX6), first to fourth selection transistors (SX1-SX4), and first to fourth DCG transistors (GX1-GX4).

Each of the first to sixteenth photoelectric conversion elements (PD1-PD16) may generate photocharges in response to incident light within a photocharge accumulation section.

As will be discussed below, the transfer transistors (TX1-TX16, RX1-RX2, SX1-SX4, GX1-GX4) may receive electrical signals (e.g., transfer signals, reset signals, selection signals, and gain signals) through gate terminals thereof. In some implementations, the transfer transistors (TX1-TX16) may receive transfer signals through gate terminals thereof, the reset transistors (RX1-RX2) may receive reset signals through gate terminals thereof, the selection transistors (SX1-SX4) may receive selection signals through gate terminals thereof, and the DCG transistors GX1-GX4) may receive gain signals through gate terminals thereof. Each electrical signal may have a logic high level or a logic low level. When a high-level electrical signal is applied to a gate of a transistor, the transistor may be turned on. When a low-level electrical signal is applied to a gate of a transistor, the transistor may be turned off. However, the present disclosure is not limited thereto. In another example, the transistor may be implemented as PMOS transistor, and thus may be turned on by a low-level electrical signal, and turned off by a high-level electrical signal.

The first to sixteenth transfer transistors (TX1-TX16) may receive the transfer signals (TS1-TS16) through gate terminals thereof, respectively. When each of the first to sixteenth transfer transistors (TX1-TX16) is turned on, photocharges may move to the first or second floating diffusion node (FD1, FD2), and when each of the first to sixteenth transfer transistors (TX1-TX16) is turned off, photocharges accumulated in the first to sixteenth photoelectric conversion elements (PD1-PD16) may be prevented from moving to the first or second floating diffusion node (FD1, FD2).

For example, the first transfer transistor (TX1) is turned on during a pixel readout period to transfer photocharges generated by the first photoelectric conversion element (PD1) to the first floating diffusion node (FD1). The ninth transfer transistor (TX9) may be turned on during the pixel readout period to transfer photocharges generated by the ninth photoelectric conversion element (PD9) to the second floating diffusion node (FD2). The pixel readout period may occur after the photocharge accumulation period.

In an embodiment, some of the first to sixteenth transfer transistors (TX1-TX16) may be turned on simultaneously. In another embodiment, the first to sixteenth transfer transistors (TX1-TX16) may be sequentially turned on and off, such that one transistor is turned on and then turned off before the next transistor is turned on and then turned off. For example, one of the first to sixteenth transfer transistors (TX1-TX16) is turned on and then turned off, and then the next transistor among the first to sixteenth transfer transistors (TX1-TX16) is turned on and then turned off. This process continues sequentially until the last transistor among the first to sixteenth transfer transistors (TX1-TX16) is finally turned on and turned off.

The first and second reset transistors (RX1, RX2) may receive the reset signals (RS1, RS2) through gate terminals of the first and second reset transistors (RX1, RX2), respectively. For example, the first reset transistor (RX1) may receive the reset signal (RS1) through a gate terminal of the first reset transistor (RX1), and the second reset transistor (RX2) may receive the reset signal (RS2) through a gate terminal of the second reset transistor (RX2). The first reset transistor (RX1) may be turned on during the pixel reset period to reset a voltage of the first floating diffusion node (FD1) to a power-supply voltage (VDD). The second reset transistor (RX2) may be turned on during the pixel reset period to reset a voltage of the second floating diffusion node (FD2) to the power-supply voltage (VDD). In this case, the pixel reset period may be located before the pixel readout period.

The first floating diffusion node (FD1) may have a first capacitance (CFD1) as its intrinsic capacitance. The second floating diffusion node (FD2) may have a second capacitance (CFD2) as its intrinsic capacitance.

The first to eighth transfer transistors (TX1-TX8) and the first floating diffusion node (FD1) may be electrically connected to each other through a first central electrical interconnect line. The ninth to sixteenth transfer transistors (TX9-TX16) and the second floating diffusion node (FD2) may be electrically connected to each other through a second central electrical interconnect line.

In the pixel readout period, each of the first to third drive transistors (DX1-DX3) may receive a voltage of the first floating diffusion node (FD1) through a gate terminal of each of the first to third drive transistors (DX1-DX3). The first to third drive transistors (DX1-DX3) may amplify an electrical signal corresponding to a voltage level of the first floating diffusion node (FD1), and may transmit the amplified electrical signal to the first and second selection transistors (SX1-SX2). The first to third drive transistors (DX1-DX3) may be connected to the power-supply voltage (VDD) through drain terminals of the first to third drive transistors (DX1-DX3).

In the pixel readout period, each of the fourth to sixth drive transistors (DX4-DX6) may receive a voltage of the second floating diffusion node (FD2) through a gate terminal of each of the fourth to sixth drive transistors (DX4-DX6). The fourth to sixth drive transistors (DX4-DX6) may amplify an electrical signal corresponding to a voltage level of the second floating diffusion node (FD2), and may transmit the amplified electrical signal to the third and fourth selection transistors (SX3-SX4). The fourth to sixth drive transistors (DX4-DX6) may be connected to the power-supply voltage (VDD) through drain terminals of the fourth to sixth drive transistors (DX4-DX6).

The first to fourth selection transistors (SX1-SX4) may receive selection signals (SS1-SS4) through gate terminals of the first to fourth selection transistors (SX1, SX2, SX3, or SX4), respectively. When each of the first and second selection transistors (SX1-SX2) is turned on in response to a corresponding selection signal (SS1-SS4), the amplified electrical signal output from the first to third drive transistors (DX1-DX3) may be output to a column bus line (CBL). When each of the third and fourth selection transistors (SX3-SX4) is turned on in response to a corresponding selection signal (SS1-SS4), the amplified electrical signals output from the fourth to sixth drive transistors (DX4-DX6) may be output to the column bus line (CBL).

When operating the plurality of drive transistors (or the plurality of selection transistors) connected in parallel, output impedance is reduced as compared to using only a single drive transistor, thereby decreasing electrical signal distortion and improving signal transmission efficiency. In addition, since the current is distributed among a plurality of transistors, heat load on each transistor is reduced. As a result, overheating of the transistors can be prevented, enhancing the heat management efficiency of the image sensing device 1 and improving the reliability and lifespan of the transistors. In addition, since the transistors connected in parallel can distribute noise of each transistor, overall noise can be reduced and the signal-to-noise ratio (SNR) of the pixel signal can be improved. In another example, each of the driver transistor and the selection transistor connected to the first floating diffusion node (FD1) or the second floating diffusion node (FD2) may be implemented as one single transistor.

The first to fourth DCG transistors (GX1-GX4) may receive gain signals (GS1-GS4) through gate terminals of the first to fourth DCG transistors (GX1-GX4), respectively. Each of the gain signals (GS1-GS4) may have a high level during the pixel readout period.

The first DCG transistor (GX1) may be electrically connected to the first floating diffusion node (FD1). The first DCG transistor (GX1) may have a first parasitic capacitor (not shown). When the first DCG transistor (GX1) is turned on, a current may flow between the first floating diffusion node (FD1) and the first parasitic capacitor, increasing the capacitance of the first floating diffusion node (FD1). When the capacitance of the first floating diffusion node (FD1) increases, a voltage per unit charge may decrease, leading to a decrease in the conversion gain.

The second DCG transistor (GX2) may be electrically connected to the first DCG transistor (GX1). The second DCG transistor (GX2) may include a second parasitic capacitor (not shown). When the first DCG transistor (GX1) and the second DCG transistor (GX2) are turned on, the capacitance of the first floating diffusion node (FD1) may further increase. When the capacitance of the first floating diffusion node (FD1) further increases, a voltage per unit charge may further decrease, leading to a further decrease in the conversion gain.

The third DCG transistor (GX3) may be electrically connected to the second floating diffusion node (FD2). The third DCG transistor (GX3) may be electrically connected to the first floating diffusion node (FD1). The third DCG transistor (GX3) may include a third parasitic capacitor (not shown). When the third DCG transistor (GX3) is turned on, the current may flow between the second floating diffusion node (FD2) and the third parasitic capacitor, so that capacitance of the second floating diffusion node (FD2) may increase. When the capacitance of the second floating diffusion node (FD2) increases, the voltage per unit charge may decrease, leading to a decrease in the conversion gain.

The fourth DCG transistor (GX4) may be electrically connected to the fourth DCG transistor (GX4). The fourth DCG transistor (GX4) may be electrically connected to the second DCG transistor (GX2). The fourth DCG transistor (GX4) may include a fourth parasitic capacitor (not shown). When the third DCG transistor (GX3) and the fourth DCG transistor (GX4) are turned on, the capacitance of the second floating diffusion node (FD2) may further increase. When the capacitance of the second floating diffusion node (FD2) further increases, the voltage per unit charge may further decrease, leading to a further decrease in the conversion gain.

The image sensing device 1 based on some embodiments of the disclosed technology can implement, for example, a triple conversion gain (TCG). The triple conversion gain may include a high conversion gain (HCG), a middle conversion gain (MCG), and a low conversion gain (LCG).

When all of the first to fourth DCG transistors (GX1-GX4) are turned on, an electrical signal generated by each of the first to sixteenth photoelectric conversion elements (PD1-PD16) in response to incident light may be output with a low conversion gain.

When the first DCG transistor (GX1) is turned on and the second to fourth DCG transistors (GX2-GX4) are turned off, an electrical signal generated by each of the first to eighth photoelectric conversion elements (PD1-PD8) in response to incident light may be output with a middle conversion gain.

When the third DCG transistor (GX3) is turned on and the first, second, and fourth DCG transistors (GX1, GX2, GX4) are turned off, an electrical signal generated by each of the ninth to sixteenth photoelectric conversion elements (PD1-PD16) in response to incident light may be output with a middle conversion gain.

When all of the first to fourth DCG transistors (GX1-GX4) are turned off, an electrical signal generated by each of the first to sixteenth photoelectric conversion elements (PD1-PD16) in response to incident light may be output with a high conversion gain.

In an embodiment of the disclosed technology, the high conversion gain may be eight times the low conversion gain. The middle conversion gain may be twice the low conversion gain. In this way, the conversion gain ratio of the triple conversion gain may be 1:2:8. However, the present disclosure is not limited thereto, and the conversion gain ratio may be variously designed by adjusting the sizes of the first to fourth DCG transistors (GX1-GX4) as well as the first and second capacitances CFD1 and CFD2.

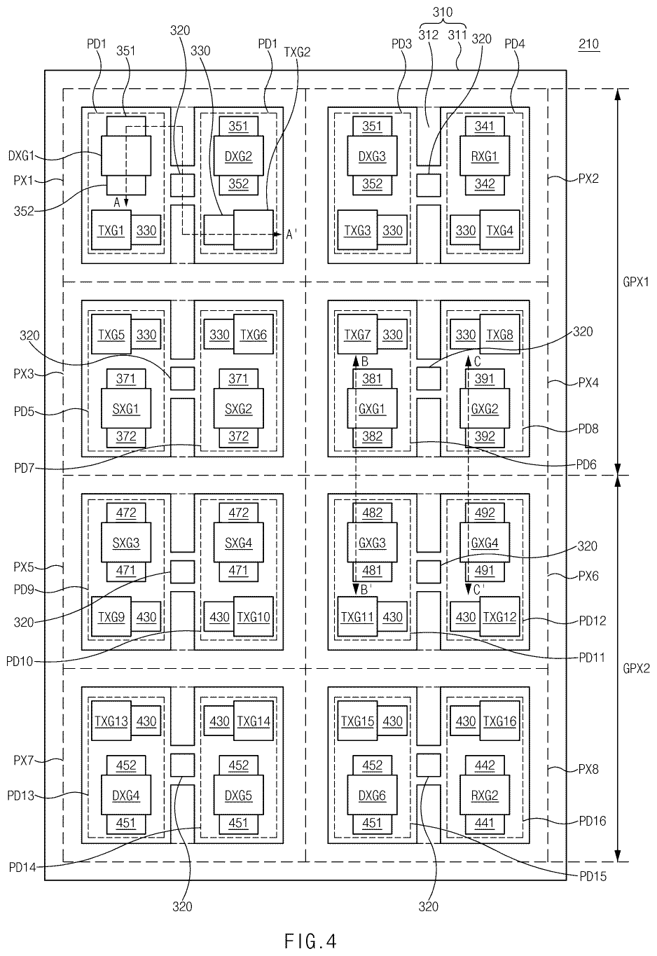

FIG. 4 is a plan view illustrating an example of the first pixel region 210 shown in FIG. 2 based on some embodiments of the disclosed technology.

Hereinafter, some redundant descriptions overlapping with FIG. 3 will be omitted.

Referring to FIGS. 3 and 4, the first pixel region 210 may include a first pixel group (GPX1), a second pixel group (GPX2), and a pixel isolation structure 310.

The pixel isolation structure 310 may include a first pixel isolation structure 311 and a second pixel isolation structure 312.

The first pixel isolation structure 311 may be arranged in a grid shape along one or more boundaries between pixels. The first pixel isolation structure 311 arranged in the grid shape may define the plurality of pixels. Each region surrounded by the first pixel isolation structure 311 may constitute each pixel. The first pixel isolation structure 311 may optically isolate adjacent pixels from each other. The first pixel isolation structure 311 may include, for example, an insulation layer (e.g., SiO₂ , etc.) or a conductive layer (e.g., polysilicon, polysilicon including impurities, etc.).

The second pixel isolation structure 312 may extend from the first pixel isolation structure 311 toward the inside of each pixel. The second pixel isolation structure 312 may extend from each of two facing side surfaces of the first pixel isolation structure 311 toward the inside of each pixel. The second pixel isolation structure 312 may reduce crosstalk between two different photoelectric conversion elements arranged within one pixel. The second pixel isolation structure 312 may include, for example, an insulation layer (e.g., SiO₂ , etc.) or a conductive layer (e.g., polysilicon, polysilicon including impurities, etc.).

The first pixel group (GPX1) may include first to fourth pixels (PX1-PX4). The first pixel group (GPX1) may be formed to have a structure in which the first to fourth pixels (PX1-PX4) are arranged in a (2×2) matrix structure.

Referring to the constituent components included in each of the first to fourth pixels (PX1-PX4), the first pixel (PX1) may include first and second transfer gates (TXG1, TXG2), first and second photoelectric conversion elements (PD1, PD2), a ground region 320, and a first floating diffusion region 330.

Each of the first photoelectric conversion element (PD1) and the second photoelectric conversion element (PD2) may generate photocharges in response to incident light. The first photoelectric conversion element (PD1) may be spaced apart from the second photoelectric conversion element (PD2). The second pixel isolation structure 312 may be disposed between the first photoelectric conversion element (PD1) and the second photoelectric conversion

### Element (pd2).

The first transfer gate (TXG1) may include an electrode layer including a conductive material (e.g., polysilicon, metal, etc.) and an insulation layer including an insulation material (e.g., silicon oxide, etc.). The first transfer gate (TXG1) may receive the operating voltage through a predetermined contact-interconnect line (hereinafter referred to as a first transfer transistor contact-interconnect line). The first transfer gate (TXG1) may be a gate of the first transfer transistor (TX1). The first transfer gate (TXG1) may overlap the first photoelectric conversion element (PD1).

Each of the various gates to be described below may include an electrode layer including a conductive material (e.g., polysilicon, metal, etc.) and an insulation layer including an insulation material (e.g., silicon oxide, etc.).

The second transfer gate (TXG2) may be a gate of the second transfer transistor (TX2). The second transfer gate (TXG2) may receive the operating voltage through a predetermined contact-interconnect line (hereinafter referred to as a second transfer transistor contact-interconnect line). When the operating voltage is applied to the second transfer gate (TXG2), photocharges generated and accumulated in the second photoelectric conversion element (PD2) may move to the first floating diffusion region 330. The second transfer gate (TXG2) may overlap the second photoelectric conversion element (PD2).

The first floating diffusion region 330 may be adjacent to each of the first photoelectric conversion element (PD1) and the second photoelectric conversion element (PD2). The first floating diffusion region 330 may store photocharges generated by the first photoelectric conversion element (PD1) and/or the second photoelectric conversion element (PD2), and a voltage corresponding to the stored photocharges may be applied to one or more drive gates (DXG1, DXG2). Each of the plurality of first floating diffusion regions 330 may be arranged to correspond to one photoelectric conversion element and one transfer gate, so that the first floating diffusion regions 330 may be arranged adjacent to the transfer gates one by one. For example, one first floating diffusion region 330 may be arranged adjacent to the first transfer gate (TXG1), and another first floating diffusion region 330 may be arranged adjacent to the second transfer gate (TXG2), and these two first floating diffusion regions 330 may be arranged separately from each other. The plurality of first floating diffusion regions 330 may be electrically connected through a single electrical interconnect line (hereinafter referred to as a first central electrical interconnect line).

The ground region 320 may be arranged between the second pixel isolation structures 312 facing each other. The ground region 320 may be a region to which a ground voltage is applied. When the ground voltage is applied to the ground region 320, electrical potentials of the constituent components included in the pixel can be stabilized, and for example, the well capacity of the photoelectric conversion elements may be maintained constant.

Each of the second to fourth pixels (PX2-PX4) may also include at least two photoelectric conversion elements, gates of at least two transfer transistors, and at least one floating diffusion regions, and the same content as that of the first pixel (PX1) may be applied to each of the second to fourth pixels (PX2-PX4). For example, the second pixel (PX2) may include third and fourth photoelectric conversion elements (PD3, PD4), third and fourth transfer gates (TXG3, TXG4), and first floating diffusion regions 330. For example, photocharges generated by the third photoelectric conversion element (PD3) in response to incident light may move to the first floating diffusion region 330 when the operating voltage is applied to the third transfer gate (TXG3).

In addition, the plurality of first floating diffusion regions 330 included in the first to fourth pixels (PX1-PX4) may all be electrically connected through the first central electrical interconnect line.

Referring to the configurations shared by the first to fourth pixels (PX1-PX4), the first pixel (PX1) may include first and second drive gates (DXG1, DXG2), a drive drain region 351, and a drive source region 352. The second pixel (PX2) may include a third drive gate (DXG3), a first reset gate (RXG1), a drive drain region 351, a drive source region 352, a first reset drain region 341, and a first reset source region 342. The third pixel (PX3) may include first and second selection gates (SXG1, SXG2), a selection drain region 371, and a selection source region 372. The fourth pixel (PX4) may include first and second DCG gates (GXG1, GXG2), a first DCG source region 381, a first DCG drain region 382, a second DCG source region 391, and a second DCG drain region 392.

Each of the first to third drive gates (DXG1-DXG3) may receive a voltage corresponding to photocharges accumulated in the first floating diffusion region 330. Each of the first to third drive gates (DXG1-DXG3) may be electrically connected to the first floating diffusion region 330 through a first central electrical interconnect line. When the voltage is applied to the gates (DXG1-DXG3) of the first to third drive transistors, the first to third drive transistors (DX1-DX3) having gate terminals receiving the operating voltage may amplify an electrical signal to be applied to the first and second selection transistors (SX1, SX2).

The first drive gate (DXG1) may be a gate of the first drive transistor (DX1). The second drive gate (DXG2) may be a gate of the second drive transistor (DX2). The third drive gate (DXG3) may be a gate of the third drive transistor (DX3). The first drive gate (DXG1) may overlap the first photoelectric conversion element (PD1). The second drive gate (DXG2) may overlap the second photoelectric conversion element (PD2). The third drive gate (DXG3) may overlap the third photoelectric conversion element (PD3).

The drive drain region 351 may be a region configured to receive a power-supply voltage VDD (see FIG. 3) as an input. The drive drain region 351 may have a structure corresponding to the drain terminals of the first to third drive transistors (DX1-DX3). The drive drain region 351 may be adjacent to each of the first and second drive gates (DXG1, DXG2).

The drive source region 352 may be electrically connected to the selection source region 372 through a predetermined electrical interconnect line (hereinafter referred to as a drive electrical interconnect line). The drive source region 352 may be used as an output node of each of the first to third drive transistors (DX1-DX3), and the amplified electrical signal may be output to the source terminals of the selection transistors (SX1 to SX2). The drive source region 352 may be a structure corresponding to the source terminals of the first to third drive transistors (DX1-DX3). The drive source region 352 may be adjacent to each of the first and second drive gates (DXG1, DXG2), and may be spaced apart from the drive drain region 351.

The first reset gate (RXG1) may be a gate of the first reset transistor (RX1). For example, when the operating voltage is applied to the first reset gate (RXG1) during the pixel reset period, the voltage of the first floating diffusion region 330 may be reset to the power-supply voltage (VDD). When the pixel readout period is performed after the voltage of the first floating diffusion region 330 is reset to the power-supply voltage (VDD), the accuracy of the intensity of the pixel signal to be output in response to the amount of photocharges generated by the photoelectric conversion element may increase. The first reset gate (RXG1) may overlap the fourth photoelectric conversion element (PD4).

The first reset drain region 341 may be a region configured to receive the power-supply voltage VDD (see FIG. 3). The first reset drain region 341 may be configured to correspond to a drain terminal of the first reset transistor (RX1). The first reset drain region 341 may be adjacent to the first reset gate (RXG1).

The first reset source region 342 may be electrically connected to the first floating diffusion region 330 through the first central electrical interconnect line. The first reset source region 342 may be configured to correspond to a source terminal of the first reset transistor (RX1). The first reset source region 342 may be adjacent to the first reset gate (RXG1).

The first selection gate (SXG1) may be a gate of the first selection transistor (SX1). The second selection gate (SXG2) may be a gate of the second selection transistor (SX2). The first selection gate (SXG1) may overlap the fifth photoelectric conversion element (PD5). The second selection gate (SXG2) may overlap the sixth photoelectric conversion element (PD6). When the operating voltage is applied to the first selection gate (SXG1) and/or the second selection gate (SXG1), the amplified electrical signal may be output to a column bus line (CBL) (see FIG. 3). The amplified electrical signal may be transmitted to the CDS 130 (see FIG. 1) through the column bus line (CBL of FIG. 3).

The selection drain region 371 may be electrically connected to the column bus line (CBL) (see FIG. 3) through a predetermined electrical interconnect line (referred to hereinafter as a selection electrical interconnect line). The selection drain region 371 may be configured to correspond to the drain terminals of the first and second selection transistors (SX1, SX2). The selection drain regions 371 may be adjacent to the first selection gate (SXG1) and the second selection gate (SXG2), respectively.

The selection drain region 371 may be electrically connected to a column bus line CBL (see FIG. 3) by a predetermined electrical interconnect line (hereinafter, referred to as a selection electrical interconnect line). The selection drain region 371 may correspond to a drain terminal of the first and second selection transistors SX1 to SX2. Each of the select drain regions 371 may be adjacent to each of the first select gate SXG1 and the second select gate SXG2.

The selection source region 372 may be electrically connected to the drive source region 352 through the drive electrical interconnect line. The selection source region 372 may be configured to correspond to the source terminals of the first and second selection transistors (SX1, SX2). The selection source regions 372 may be adjacent to the first selection gate (SXG1) and the second selection gate (SXG2), respectively.

The first DCG gate (GXG1) may be a gate of the first DCG transistor (GX1). The first DCG gate (GXG1) may overlap the seventh photoelectric conversion element (PD7). When the operating voltage is applied to the first DCG gate (GXG1), the conversion gain of the first pixel group (GPX1) or the conversion gain of each pixel included in the first pixel group (GPX1) may be adjusted. For example, the conversion gain of the first pixel (PX1) may be adjusted. The first DCG gate (GXG1) may receive the operating voltage through a predetermined electrical interconnect line (hereinafter referred to as a first DCG contact-interconnect line). The first DCG gate (GXG1) may be arranged to be close to the sixth pixel (PX6) including the third DCG gate (GXG3) from the center of the fourth pixel (PX4).

The first DCG source region 381 may be electrically connected to the first floating diffusion region 330 through the first central electrical interconnect line. The first DCG source region 381 may be arranged adjacent to the first DCG gate (GXG1). The first DCG source region 381 may be a structure corresponding to the source terminal of the first DCG transistor (GX1).

The first DCG drain region 382 may be electrically connected to a third DCG drain region 482 through a predetermined electrical interconnect line (hereinafter referred to as a first DCG electrical interconnect line). The first DCG drain region 382 may be electrically connected to a second DCG source region 391 through a predetermined electrical interconnect line (hereinafter referred to as a third DCG electrical interconnect line). The third DCG electrical interconnect line may be spaced apart from the first DCG electrical interconnect line or may be in contact with the first DCG electrical interconnect line. The first DCG drain region 382 may be a structure corresponding to the drain terminal of the first DCG transistor (GX1). The first DCG drain region 382 may be arranged adjacent to the first DCG gate (GXG1). For example, the first DCG drain region 382 may be arranged adjacent to the first DCG gate (GXG1) at a position closer to the sixth pixel (PX6) than the first DCG source region 381. As the first DCG drain region 382 is located closer to a boundary between the fourth pixel (PX4) and the sixth pixel (PX6) or a boundary between the first pixel group (GPX1) and the second pixel group (GPX2), the length of the first DCG electrical interconnect line may be shortened.

As the length of the DCG electrical interconnect line increases, parasitic resistance and parasitic capacitance of the DCG transistors increase, so that the conversion gain value of the DCG transistor may no longer be suitable since the DCG ratio between a low conversion gain state and a high conversion gain state may be modified. As a result, as the first DCG electrical interconnect line becomes shorter in length, the conversion gain value of the DCG transistor may be designed more accurately. For example, when a gate (GXG1) of the first DCG transistor and a gate (GXG3) of the third DCG transistor are disposed to be biased from the center of each pixel in a direction in which the gate (GXG1) and the gate (GXG3) are located closer to the each other, the length of the first DCG electrical interconnect line may be shortened, and a more accurate conversion gain ratio design may be possible.

The second DCG gate (GXG2) may be a gate of the second DCG transistor (GX2). The second DCG gate (GXG2) may overlap the eighth photoelectric conversion element (PD8). When the operating voltages of the first and second DCG transistors (GX1, GX2) are respectively applied to the first and second DCG gates (GXG1, GXG2), the conversion gain of the first pixel group (GPX1) or the conversion gain of each pixel included in the first pixel group (GPX1) may be adjusted. For example, the conversion gain of the first pixel (PX1) may be adjusted. The second DCG gate (GXG2) may receive the operating voltage through a predetermined electrical interconnect line (hereinafter referred to as a second DCG contact-interconnect line). The second DCG gate (GXG2) may be arranged to be close to the sixth pixel (PX6) including the fourth DCG gate (GXG4) from the center of the fourth pixel (PX4).

The second DCG source region 391 may be electrically connected to the first DCG drain region 382 through the third DCG electrical interconnect line. The second DCG source region 391 may be arranged adjacent to the second DCG gate (GXG2). The second DCG source region 391 may be configured to correspond to the source terminal of the second DCG transistor (GX2).

The second DCG drain region 392 may be electrically connected to the fourth DCG drain region 492 through a predetermined electrical interconnect line (hereinafter referred to as a second DCG electrical interconnect line). The second DCG drain region 392 may be configured to correspond to the drain terminal of the second DCG transistor (GX2). The second DCG drain region 382 may be arranged adjacent to the second DCG gate (GXG2). For example, the second DCG drain region 392 may be arranged adjacent to the second DCG gate (GXG2) at a position closer to the sixth pixel (PX6) than the second DCG source region 391. As the second DCG drain region 392 is located closer to a boundary between the fourth pixel (PX4) and the sixth pixel (PX6) or a boundary between the first pixel group (GPX1) and the second pixel group (GPX2), the length of the second DCG electrical interconnect line may be shortened.

The positions of the first and second selection transistors (SX1, SX2), the positions of the first to third drive transistors (DX1-DX3), and the positions of the first reset transistors (RX1) from among the constituent components included in the first pixel group (GPX1) may be interchanged as needed.

The second pixel group (GPX2) may include the fifth to eighth pixels (PX5-PX8) and a pixel isolation structure 310. The second pixel group (GPX2) may be formed to have a structure in which the fifth to eighth pixels (PX5-PX8) are arranged in a (2×2) matrix structure.

In an embodiment, the constituent components included in the second pixel group (GPX2) may be arranged vertically symmetrical to the constituent components included in the first pixel group (GPX1) based on the boundary between the first pixel group (GPX1) and the second pixel group (GPX2). For example, the first pixel (PX1) may be arranged symmetrical to the seventh pixel (PX7) based on the above boundary. The second pixel (PX2) may be arranged symmetrical to the eighth pixel (PX8) with respect to the above boundary. The third pixel (PX3) may be arranged symmetrical to the fifth pixel (PX5) with respect to the boundary. The fourth pixel (PX4) may be arranged symmetrical to the sixth pixel (PX6) with respect to the above boundary.

In the present document, the above-described symmetrical relationship between the pixels may mean, for example, that the first DCG gate (GXG1) of the fourth pixel (PX4) and the third DCG gate (GXG3) of the sixth pixel (PX6) are disposed at positions symmetrical to each other with respect to the above boundary.

In configurations having a symmetrical relationship in some embodiments, the symmetrical relationship among the constituent components does not need to be strictly determined mathematically based on whether their distances from the boundaries of the constituent components are exactly equal, and may be adjusted due to variables or limitations in the fabrication process. In addition, to reduce the length of the first DCG electrical interconnect line and the length of the second DCG electrical interconnect line, the above-described symmetrical relationship may include an arrangement where the first DCG transistor (GX1) (or the second DCG transistor GX2) and the third DCG transistor (GX3) (or the fourth DCG transistor GX4), which belong to different pixel groups, are arranged to face each other with respect to the above boundary interposed therebetween.

The constituent components (e.g., the first transfer gate TXG1 overlapping the first pixel PX1 and the thirteenth transfer gate TXG13 overlapping the seventh pixel PX7) may have substantially the same role and structure under the symmetrical arrangement described above. Hereinafter, as representative examples, the fourth pixel (PX4) and the constituent components included in the fourth pixel (PX4), as well as the sixth pixel (PX6) and the constituent components included in the sixth pixel (PX6) will be described in detail.

The sixth pixel (PX6) may include eleventh and twelfth photoelectric conversion elements (PD11, PD12), eleventh and twelfth transfer gates (TXG11, TXG12), a second floating diffusion region 430, third and fourth DCG gates (GCG3, GCG4), a third DCG source region 481, a third DCG drain region 482, a fourth DCG source region 491, and a fourth DCG drain region 492.

Each of the eleventh photoelectric conversion element (PD11) and the twelfth photoelectric conversion element (PD12) may generate photocharges in response to incident light. The eleventh photoelectric conversion element (PD11) may be spaced apart from the twelfth photoelectric conversion element (PD12). The second pixel isolation structure 312 may be disposed between the eleventh photoelectric conversion element (PD11) and the twelfth photoelectric conversion element (PD12).

The eleventh transfer gate (TXG11) may receive the operating voltage through a predetermined contact-interconnect line (hereinafter referred to as an eleventh transfer transistor contact-interconnect line). When the operating voltage is applied to the gate (TXG11) of the eleventh transfer transistor, photocharges generated and accumulated in the eleventh photoelectric conversion element (PD11) may move to the second floating diffusion region 430. The eleventh transfer gate (TXG11) may be a gate of the eleventh transfer transistor (TX11).

The twelfth transfer gate (TXG12) may receive the operating voltage through a predetermined contact-interconnect line (hereinafter referred to as a twelfth transfer transistor contact-interconnect line). When the operating voltage is applied to the gate (TXG12) of the twelfth transfer transistor, photocharges generated and accumulated in the twelfth photoelectric conversion element (PD12) may move to the second floating diffusion region 430. The twelfth transfer gate (TXG12) may be a gate of the twelfth transfer transistor (TX12).

The second floating diffusion region 430 may be arranged adjacent to each of the eleventh transfer gate (TXG11) and the twelfth transfer gate (TXG12). The second floating diffusion region 430 may store photocharges generated by the eleventh and/or twelfth photoelectric conversion elements (PD11, PD12), and a voltage corresponding to the stored photocharges may be applied to the third and/or fourth drive gates (DXG3, DXG4). Each of the plurality of second floating diffusion regions 430 may be arranged to correspond to one photoelectric conversion element and one transfer gate, so that the second floating diffusion regions 430 may be arranged adjacent to the transfer gates in one-to-one correspondence. For example, one second floating diffusion region 430 may be arranged adjacent to the eleventh transfer gate (TXG11), another second floating diffusion region 430 may be arranged adjacent to the twelfth transfer gate (TXG12), and these two floating diffusion regions may be arranged to be isolated from each other. The plurality of second floating diffusion regions 430 may be electrically connected by one electrical interconnect line (hereinafter referred to as a second central electrical interconnect line).

The third DCG gate (GXG3) may be a gate of the third DCG transistor (GX3). The third DCG gate (GXG3) may overlap the eleventh photoelectric conversion element (PD11). When the operating voltage is applied to the third DCG gate (GXG3), the conversion gain of the second pixel group (GPX2) or the conversion gain of each pixel included in the second pixel group (GPX2) may be changed. For example, the conversion gain of the seventh pixel (PX7) may be changed. The third DCG gate (GXG3) may receive the operating voltage through a predetermined electrical interconnect line (hereinafter referred to as a third DCG contact-interconnect line). The third DCG gate (GXG3) may be arranged to be closer to the fourth pixel (PX4) including the first DCG gate (GXG1) from the center of the sixth pixel (PX6).

The third DCG source region 481 may be electrically connected to the second floating diffusion region 430 through the second central electrical interconnect line. The third DCG source region 481 may be arranged adjacent to the third DCG gate (GXG3). The third DCG source region 481 may be a structure corresponding to the source terminal of the third DCG transistor (GX3).

The third DCG drain region 482 may be electrically connected to the first DCG drain region 382 through a predetermined electrical interconnect line (hereinafter referred to as a first DCG electrical interconnect line). The third DCG drain region 482 may be electrically connected to the fourth DCG source region 491 through a predetermined electrical interconnect line (hereinafter referred to as a fourth DCG electrical interconnect line). The fourth DCG electrical interconnect line may be spaced apart from the first DCG electrical interconnect line or may be in contact with the first DCG electrical interconnect line. The third DCG drain region 482 may be a structure corresponding to a drain terminal of the third DCG transistor (GX3). The third DCG drain region 482 may be arranged adjacent to the third DCG gate (GXG3). For example, the third DCG drain region 482 may be arranged adjacent to the third DCG gate (GXG3) at a position closer to the fourth pixel (PX4) than the third DCG source region 481. As the third DCG drain region 482 is arranged closer to the boundary between the fourth pixel (PX4) and the sixth pixel (PX6) or the boundary between the first pixel group (GPX1) and the second pixel group (GPX2), the length of the first DCG electrical interconnect line may be shortened.

The fourth DCG gate (GXG4) may be a gate of the fourth DCG transistor (GX4). The fourth DCG gate (GXG4) may overlap the twelfth photoelectric conversion element (PD12). When the operating voltages of the third and fourth DCG transistors (GX3, GX4) are applied to the third and fourth DCG gates (GXG3, GXG4), the conversion gain of the second pixel group (GPX2) or the conversion gains of each pixel included in the second pixel group (GPX2) may be changed. For example, the conversion gain of the seventh pixel (PX7) may be changed. The fourth DCG gate (GXG4) may receive the operating voltage through a predetermined electrical interconnect line (hereinafter referred to as a fourth DCG contact-interconnect line). The fourth DCG gate (GXG4) may be arranged to be closer to the fourth pixel (PX4) including the second DCG gate (GXG2) from the center of the sixth pixel (PX6).

The fourth DCG source region 491 may be electrically connected to the third DCG drain region 482 by the fourth DCG electrical interconnect line. The fourth DCG source region 491 may be arranged adjacent to the fourth DCG gate (GXG4). The fourth DCG source region 491 may be a structure corresponding to the source terminal of the fourth DCG transistor (GX4).

The fourth DCG drain region 492 may be electrically connected to the second DCG drain region 392 through a predetermined electrical interconnect line (hereinafter referred to as the second DCG electrical interconnect line). The fourth DCG drain region 492 may be a structure corresponding to a drain terminal of the fourth DCG transistor (GX4). The fourth DCG drain region 492 may be arranged adjacent to the fourth DCG gate (GXG4). For example, the fourth DCG drain region 492 may be arranged adjacent to the fourth DCG gate (GXG4) at a position closer to the fourth pixel (PX4) than the fourth DCG source region 491. As the fourth DCG drain region 492 is disposed closer to the boundary between the sixth pixel (PX6) and the fourth pixel (PX4) or the boundary between the first pixel group (GP1) and the second pixel group (GP2), the length of the second DCG electrical interconnect line may be shortened.

The pixel array 200 based on an embodiment of the disclosed technology may be repeatedly arranged using eight pixels arranged in a (2×4) matrix structure (shown in the first pixel region 210) as a unit pixel region.

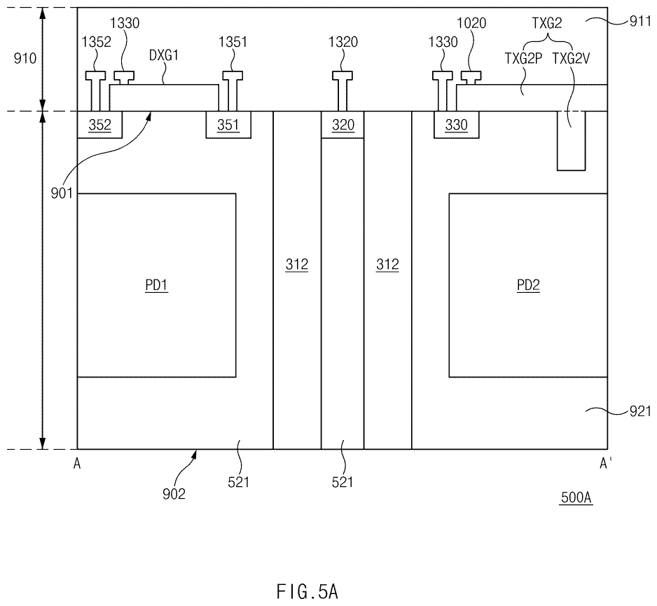

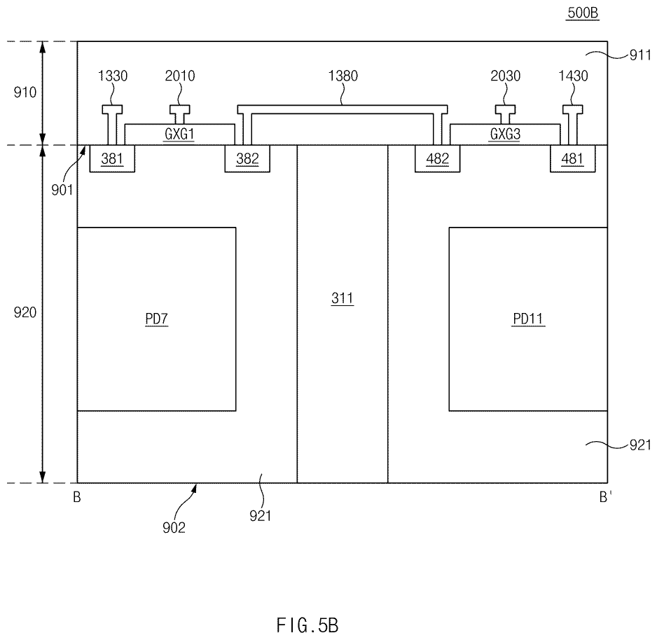

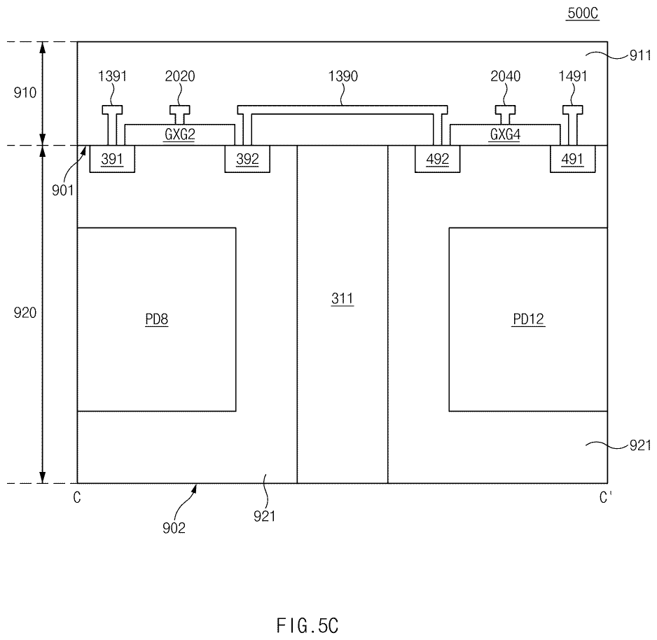

FIG. 5A is a cross-sectional view illustrating an example of the structure taken along the line A-A′ shown in FIG. 4 based on some embodiments of the disclosed technology.

Referring to FIGS. 3 to 5A, the first cross-section 500A may include an electrical interconnect line layer 910 and a photoelectric conversion layer 920.

The photoelectric conversion layer 920 may include a first photoelectric conversion element (PD1), a second photoelectric conversion element (PD2), a second pixel isolation structure 312, a vertical portion (TXG2V) of the gate of a second transfer transistor, a ground region 320, a first floating diffusion region 330, a drive drain region 351, a drive source region 352, and a semiconductor region 921. The photoelectric conversion layer 920 may include a back surface 902 upon which light from the outside is incident, and a front surface 901 facing or opposite to the back surface 902.

When the incident light is incident upon the first photoelectric conversion element (PD1) or the second photoelectric conversion element (PD2), photocharges may be generated. The generated photocharges may be accumulated in each of the photoelectric conversion elements (PD1, PD2). Each of the first photoelectric conversion element (PD1) and the second photoelectric conversion element (PD2) may include predetermined impurities. For example, each of the first photoelectric conversion element (PD1) and the second photoelectric conversion element (PD2) may be a region including impurities of a first conductivity type (e.g., N-type impurities). Each of the first photoelectric conversion element (PD1) and the second photoelectric conversion element (PD2) may be surrounded by a semiconductor region 921.

The second pixel isolation structure 312 may reduce crosstalk between the first photoelectric conversion element (PD1) and the second photoelectric conversion element (PD2) by optically blocking the first photoelectric conversion element (PD1) and the second photoelectric conversion element (PD2). The second pixel isolation structure 312 may be formed by a front-side deep trench isolation (FDTI) process in which a trench from the front surface 901 is formed, or may be formed through a back-side deep trench isolation (BDTI) process in which a trench from the back surface 902 is formed. For example, the second pixel isolation structure 312 may penetrate the photoelectric conversion layer 920.

The first floating diffusion region 330 may store photocharges moving from the second photoelectric conversion element (PD2) when the operating voltage is applied to the gate (TXG2) of the second transfer transistor. The first floating diffusion region 330 may overlap or be in contact with the gate (TXG2) of the second transfer transistor. The first floating diffusion region 330 may include predetermined impurities. For example, the first floating diffusion region 330 may be a region including impurities of the first conductivity type. The first floating diffusion region 330 may be spaced apart from the first and second photoelectric conversion elements (PD1, PD2).

The drive drain region 351 may be in contact with the power contact-interconnect line 1351. The drive drain region 351 may overlap or be in contact with the first drive gate (DXG1). The drive drain region 351 may be spaced apart from the first and second photoelectric conversion elements (PD1, PD2). The drive drain region 351 may be located near the front surface 901.

The drive source region 352 may be in contact with the drive electrical interconnect line 1352. The drive source region 352 may overlap or be in contact with the first drive gate (DXG1). The drive source region 352 may be spaced apart from the first and second photoelectric conversion elements (PD1, PD2). The drive source region 352 may be arranged near the front surface 901. The drive source region 352 and the drive drain region 351 may be arranged at both ends of the first drive gate (DXG1).

The semiconductor region 921 may surround the photoelectric conversion elements (PD1, PD2). The semiconductor region 921 may be the remaining region of the photoelectric conversion layer 920. The photoelectric conversion layer 920 may surround the plurality of photoelectric conversion elements (e.g., the first photoelectric conversion element PD1, the second photoelectric conversion element PD2), various source regions (e.g., the source region 352 of the drive transistor), various drain regions (e.g., the drain region 351 of the drive transistor), and pixel isolation structures (e.g., the second pixel isolation structure 312). The semiconductor region 921 may be a region that includes predetermined impurities. For example, the semiconductor region 921 may include impurities of the second conductivity type (e.g., P-type impurities).

The ground region 320 may be arranged near the front surface 901 of the photoelectric conversion layer 920 between the second pixel isolation structures 312 facing each other. The ground region 320 may be a region including predetermined impurities. For example, the ground region 320 may include impurities of the second conductivity type. The ground region 320 may have a higher concentration of the second conductive impurities than the semiconductor region 921.

The vertical portion (TXG2V) of the gate of the second transfer transistor will be described below together with the second transfer transistor (TX2).

The electrical interconnect line layer 910 may include a first drive gate (DXG1), a planar portion (TXG2P) of a gate of the second transfer transistor, a second transfer transistor contact-interconnect line 1020, a ground contact-interconnect line 1320, a first central electrical interconnect line 1330, a drive electric interconnect line 1352, a power contact-interconnect line 1351, and an interlayer insulation layer 911.

The first drive gate (DXG1) may be arranged on the front surface 901. The gate (DXG1) of the first drive transistor may overlap the first photoelectric conversion element (PD1). The gate (DXG1) of the first drive transistor may be in contact with the first central electrical interconnect line 1330.

The second transfer gate (TXG2) may include the planar portion (TXG2P) and the vertical portion (TXG2V) of the gate of the second transfer transistor. The planar portion (TXG2P) of the gate of the second transfer transistor may be disposed on the front surface 901. The planar portion (TXG2P) of the gate of the second transfer transistor may overlap the second photoelectric conversion element (PD2). The vertical portion (TXG2V) of the second transfer transistor may be recessed from the bottom surface of the planar portion (TXG2P) of the gate of the second transfer transistor into the photoelectric conversion layer 920. The second transfer gate (TXG2) may be in contact with the second transfer transistor contact-interconnect line 1020.

The second transfer transistor contact-interconnect line 1020 may be an interconnect layer through which the operating voltage is applied to the gate (TXG2) of the second transfer transistor. The second transfer transistor contact-interconnect line 1020 may include a conductive material (e.g., a metal material).

The first central electrical interconnect line 1330 may be in contact with the first floating diffusion region 330. The first central electrical interconnect line 1330 may also be in contact with the gate (DXG1) of the first drive transistor. The first central electrical interconnect line 1330 may electrically connect the first floating diffusion region 330 to the first drive gate (DXG1). The first central electrical interconnect line 1330 may include a conductive material (e.g., a metal material).

The drive electrical interconnect line 1352 may be in contact with the drive source region 352. The drive electrical interconnect line 1352 may electrically connect the selection source region (not shown) to the drive source region 352. The drive electrical interconnect line 1352 may include a conductive material (e.g., a metal material).

The power contact-interconnect line 1351 may be in contact with the drive drain region 351. The power contact-interconnect line 1351 may apply the power-supply voltage (VDD) to the drive drain region 351. The power contact-interconnect line 1351 may include a conductive material (e.g., a metal material).

The ground contact-interconnect line 1320 may apply a ground voltage to the ground region 320. When the ground voltage is applied to the ground region 320 through the ground contact-interconnect line 1320, the voltage in the semiconductor region 921 may become the ground voltage, and the electrical potential of each of the doped regions adjacent to the semiconductor region 921 may be maintained constant.

The interlayer insulation layer 911 may be arranged between a plurality of interconnect lines spaced apart from each other in the electrical interconnect line layer 910. The interlayer insulation layer 911 may electrically insulate the plurality of interconnect lines from each other. The interlayer insulation layer 911 may include an insulation material (e.g., oxide, nitride, etc.).

FIG. 5B is a cross-sectional view illustrating an example of the structure taken along the line B-B′ shown in FIG. 4 based on some embodiments of the disclosed technology.

Hereinafter, some redundant descriptions overlapping with FIG. 5A will be omitted.

Referring to FIGS. 3 to 5B, the second cross-section 500B may include an electrical interconnect line layer 910 and a photoelectric conversion layer 920.

The photoelectric conversion layer 920 may include a seventh photoelectric conversion element (PD7), an eleventh photoelectric conversion element (PD11), a first pixel isolation structure 311, a first DCG source region 381, a first DCG drain region 382, a third DCG source region 481, and a third DCG drain region 482.

Each of the seventh photoelectric conversion element (PD7) and the eleventh photoelectric conversion element (PD11) may generate photocharges in response to incident light. The seventh photoelectric conversion element (PD7) and the eleventh photoelectric conversion element (PD11) may be spaced apart from each other with respect to the first pixel isolation structure 311 interposed therebetween. Each of the seventh photoelectric conversion element (PD7) and the eleventh photoelectric conversion element (PD11) may be a region including impurities of the first conductivity type.

The first pixel isolation structure 311 may include a conductive material (e.g., polysilicon or polysilicon including impurities) and an insulation material (e.g., silicon oxide or silicon nitride) surrounding the conductive material. In an embodiment, the first pixel isolation structure 311 may be an isolation structure formed by a recess process such as an FDTI process in which the first pixel isolation structure 311 is recessed from the front surface 901 into the photoelectric conversion layer 920. According to another embodiment, the first pixel isolation structure 311 may be an isolation structure formed by a recess process such as a BDTI process in which the first pixel isolation structure 311 is recessed from the back surface 902 into the photoelectric conversion layer 920. The first pixel isolation structure 311 may penetrate the photoelectric conversion layer 920. The first pixel isolation structure 311 may optically isolate the seventh photoelectric conversion element (PD7) and the eleventh photoelectric conversion element (PD11) from each other, and may thus reduce crosstalk between the seventh photoelectric conversion element (PD7) and the eleventh photoelectric conversion element (PD11).

The first DCG source region 381 may be in contact with the first central electrical interconnect line 1330. The first DCG source region 381 may be arranged near the front surface 901, and may be a region including impurities of the first conductivity type. The first DCG source region 381 may be spaced apart from the seventh and eleventh photoelectric conversion elements (PD7, PD11). The first DCG source region 381 may overlap or be in contact with the first DCG gate (GXG1).

The first DCG drain region 382 may be in contact with the first DCG electrical interconnect line 1380. For example, the first DCG drain region 382 may be in direct contact with the first DCG electrical interconnect line 1380. The first DCG drain region 382 may be arranged near the front surface 901, and may be a region including impurities of the first conductivity type. The first DCG drain region 382 may be spaced apart from the seventh and eleventh photoelectric conversion elements (PD7, PD11). The first DCG drain region 382 may overlap or be in contact with the first DCG gate (GXG1). The first DCG drain region 382 and the first DCG source region 381 may be arranged at both ends of the first DCG gate (GXG1).

The third DCG source region 481 may be in contact with the second central electrical interconnect line 1430. The third DCG source region 481 may be arranged near the front surface 901, and may be a region including impurities of the first conductivity type. The third DCG source region 481 may be spaced apart from the seventh and eleventh photoelectric conversion elements (PD7, PD11). The third DCG source region 481 may overlap or be in contact with the third DCG gate (GXG3).

The third DCG drain region 482 may be in contact with the first DCG electrical interconnect line 1380. For example, the third DCG drain region 482 may be in direct contact with the first DCG electrical interconnect line 1380. The third DCG drain region 482 may be arranged near the front surface 901, and may be a region including impurities of the first conductivity type. The third DCG drain region 482 may be spaced apart from the seventh and eleventh photoelectric conversion elements (PD7, PD11). The third DCG drain region 482 may overlap or be in contact with the third DCG gate (GXG3). The third DCG drain region 482 and the third DCG source region 481 may be arranged at both ends of the third DCG gate (GXG3).

The electrical interconnect line layer 910 may include an interlayer insulation layer 911, a first DCG gate (GXG1), a third DCG gate (GXG3), a first central electrical interconnect line 1330, a second central electrical interconnect line 1430, a first DCG contact-interconnect line 2010, a third DCG contact-interconnect line 2030, and a first DCG electrical interconnect line 1380.

The first DCG gate (GXG1) may be disposed on the front surface 901. The first DCG gate (GXG1) may overlap the seventh photoelectric conversion element (PD7). The gate (GXG1) of the first DCG transistor may be in contact with the first DCG contact-interconnect line 2010.

The third DCG gate (GXG3) may be disposed on the front surface 901. The third DCG gate (GXG3) may overlap the eleventh photoelectric conversion element (PD11). The gate (GXG3) of the third DCG transistor may be in contact with the third DCG contact-interconnect line 2030.

The first central electrical interconnect line 1330 may also be in contact with the first DCG source region 381. The first central electrical interconnect line 1330 may electrically connect the first DCG source region 381 to the first floating diffusion region 330.

The second central electrical interconnect line 1430 may also be in contact with the third DCG source region 481. The second central electrical interconnect line 1430 may electrically connect the third DCG source region 481 to the second floating diffusion region 430. The second central electrical interconnect line 1430 may include a conductive material (e.g., a metal material).

The first DCG contact-interconnect line 2010 may transmit the operating voltage to the gate (GXG1) of the first DCG transistor. The first DCG contact-interconnect line 2010 may include a conductive material (e.g., a metal material).

The third DCG contact-interconnect line 2030 may transmit the operating voltage to the gate (GXG3) of the third DCG transistor. The third DCG contact-interconnect line 2030 may include a conductive material (e.g., a metal material).

The first DCG electrical interconnect line 1380 may electrically connect the drain region 382 of the first DCG transistor to the drain region 482 of the third DCG transistor. For example, the first DCG electrical interconnect line 1380 may directly connect the drain region 382 of the first DCG transistor to the drain region 482 of the third DCG transistor. The first DCG electrical interconnect line 1380 may include a conductive material (e.g., a metal material). In some implementations, the first DCG transistor and the third DCG transistor are arranged to be adjacent, minimizing the length of the first DCG electrical interconnect line 1380 connecting them.

FIG. 5C is a cross-sectional view illustrating an example of the structure taken along the line C-C′ shown in FIG. 4 based on some embodiments of the disclosed technology.

Hereinafter, some redundant descriptions overlapping with FIGS. 5A and 5B will be omitted.

Referring to FIGS. 3 to 5C, the third cross-section 500C may include an electrical interconnect line layer 910 and a photoelectric conversion layer 920.

The photoelectric conversion layer 920 may include an eighth photoelectric conversion element (PD8), a twelfth photoelectric conversion element (PD12), a first pixel isolation structure 311, a second DCG source region 391, a third DCG drain region 392, a fourth DCG source region 491, and a fourth DCG drain region 492.

When incident light is incident upon the eighth photoelectric conversion element (PD8) or the twelfth photoelectric conversion element (PD12), photocharges may be generated. The generated photocharges may be accumulated in each of the photoelectric conversion elements (PD8, PD12). The first pixel isolation structure 311 may reduce crosstalk between the eighth photoelectric conversion element (PD8) and the twelfth photoelectric conversion element (PD12) by optically blocking the eighth photoelectric conversion element (PD8) and the twelfth photoelectric conversion element (PD12).

Each of the eighth photoelectric conversion element (PD8) and the twelfth photoelectric conversion element (PD12) may include predetermined impurities. For example, each of the eighth photoelectric conversion element (PD8) and the twelfth photoelectric conversion element (PD12) may be a region including impurities of the first conductivity type.

The second DCG source region 391 may be in contact with the third DCG electrical interconnect line 1391. Although not shown in FIG. 5C, the third DCG electrical interconnect line 1391 may electrically connect the first DCG drain region 382 (see FIG. 3) to the second DCG source region 391. The second DCG source region 391 may be arranged near the front surface 901, and may be a region including impurities of the first conductivity type. The second DCG source region 391 may be spaced apart from the eighth and twelfth photoelectric conversion elements (PD8, PD12). The second DCG source region 391 may overlap or be in contact with the second DCG gate (GXG2).

The second DCG drain region 392 may be in contact with the second DCG electrical interconnect line 1390. For example, the second DCG drain region 392 may be in direct contact with the second DCG electrical interconnect line 1390. The second DCG drain region 392 may be arranged near the front surface 901, and may be a region including impurities of the first conductivity type. The second DCG drain region 392 may be spaced apart from the eighth and twelfth photoelectric conversion elements (PD8, PD12). The second DCG drain region 392 may overlap or be in contact with the second DCG gate (GXG2). The second DCG drain region 392 and the second DCG source region 391 may be arranged at both ends of the second DCG gate (GXG2).

The fourth DCG source region 491 may be in contact with the fourth DCG electrical interconnect line 1491. The fourth DCG source region 491 may be arranged near the front surface 901, and may be a region including impurities of the first conductivity type. The fourth DCG source region 491 may be spaced apart from the eighth and twelfth photoelectric conversion elements (PD8, PD12). The fourth DCG source region 491 may overlap or be in contact with the fourth DCG gate (GXG4).

The fourth DCG drain region 492 may be in contact with the second DCG electrical interconnect line 1390. For example, the fourth DCG drain region 492 may be in direct contact with the second DCG electrical interconnect line 1390.The fourth DCG drain region 492 may be arranged near the front surface 901, and may be a region including impurities of the first conductivity type. The fourth DCG drain region 492 may be spaced apart from the eighth and twelfth photoelectric conversion elements (PD8, PD12). The fourth DCG drain region 492 may overlap or be in contact with the fourth DCG gate (GXG4). The fourth DCG drain region 492 and the fourth DCG source region 491 may be arranged at both ends of the fourth DCG gate (GXG4).

The electrical interconnect line layer 910 may include a second DCG gate (GXG2), a fourth DCG gate (GXG4), a second DCG electrical interconnect line 1390, a second DCG contact-interconnect line 2020, a fourth DCG contact-interconnect line 2040, a third DCG electrical interconnect line 1391, and a fourth DCG electrical interconnect line 1491.

The second DCG gate (GXG2) may be disposed on the front surface 901. The second DCG gate (GXG2) may overlap the eighth photoelectric conversion element (PD8). The second DCG gate (GXG2) may be in contact with the second DCG contact-interconnect line 2020.

The fourth DCG gate (GXG4) may be disposed on the front surface 901. The fourth DCG gate (GXG4) may overlap the twelfth photoelectric conversion element (PD12). The fourth DCG gate (GXG4) may be in contact with the fourth DCG contact-interconnect line 2040.

The second DCG electrical interconnect line 1390 may electrically connect the second DCG drain region 392 to the fourth DCG drain region 492. The second DCG electrical interconnect line 1390 may include a conductive material (e.g., a metal material).

The second DCG contact-interconnect line 2020 may transmit the operating voltage to the second DCG gate (GXG2). The second DCG contact-interconnect line 2020 may include a conductive material (e.g., a metal material).

The fourth DCG contact-interconnect line 2040 may transmit the operating voltage to the fourth DCG gate (GXG4). The fourth DCG contact-interconnect line 2040 may include a conductive material (e.g., a metal material).

The third DCG electrical interconnect line 1391 may be in contact with the second DCG source region 391. Although not shown in FIG. 5C, the third DCG electrical interconnect line 1391 may electrically connect the first DCG drain region 382 to the second DCG source region 391. The third DCG electrical interconnect line 1391 may include a conductive material (e.g., a metal material).

The fourth DCG electrical interconnect line 1491 may be in contact with the fourth DCG source region 491. Although not shown in FIG. 5C, the fourth DCG electrical interconnect line 1491 may electrically connect the third DCG drain region 482 (see FIG. 5B) to the fourth DCG source region 491. The fourth DCG electrical interconnect line 1491 may include a conductive material (e.g., a metal material).

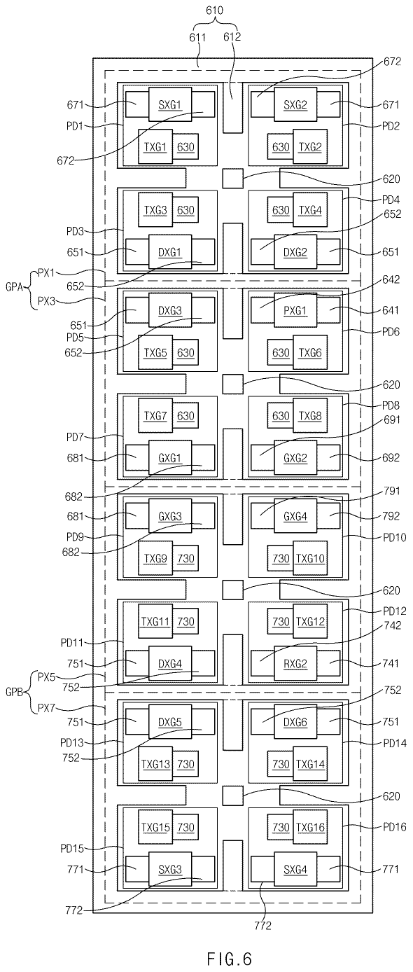

FIG. 6 is a plan view illustrating another example of the second pixel region 220 shown in FIG. 2 based on some embodiments of the disclosed technology.

Hereinafter, some redundant descriptions overlapping with FIG. 4 will be omitted.

Referring to FIGS. 2, 3, 4, and 6, the embodiment of FIG. 6 may be modeled as a circuit diagram that is the same as the circuit diagram of FIG. 3. The roles and materials of the constituent components of FIG. 6, the types of impurities including such materials, etc. are substantially the same as those of FIG. 4, but the arrangement positions of the respective components differ therefrom.

The second pixel region 220 may include a pixel isolation structure 610, a third pixel group (GPA), and a fourth pixel group (GPB).

The pixel isolation structure 610 may include a first pixel isolation structure 611 and a second pixel isolation structure 612.

The first pixel isolation structure 611 may be substantially the same as the first pixel isolation structure 311 of FIG. 4. The first pixel isolation structure 611 may be arranged along the boundaries between the first, third, fifth, and seventh pixels (PX1, PX3, PX5, PX7) to surround each of the pixels.

The second pixel isolation structure 612 may extend from the first pixel isolation structure 611 toward the inside of each pixel at four side surfaces of each of the pixels (e.g., PX1, PX3, PX5, PX7). The extended second pixel isolation structures 612 may be spaced apart from each other.

The third pixel group (GPA) may include the first pixel (PX1) and the third pixel (PX3). The first pixel (PX1) and the third pixel (PX3) may be in contact with each other. Although FIG. 6 shows only the first pixel (PX1) that contacts the third pixel (PX3) in the vertical direction for convenience of description, the disclosed technology is not limited thereto, and it should be noted that other configurations in which the first pixel (PX1) contacts the third pixel (PX3) in the horizontal direction are also possible.

Referring to the constituent components included in each of the first pixel (PX1) and the third pixel (PX3), the first pixel (PX1) may include first to fourth photoelectric conversion elements (PD1-PD4), a ground region 620, a first floating diffusion region 630, and first to fourth transfer gates (TXG1-TXG4). The third pixel (PX3) may include fifth to eighth photoelectric conversion elements (PD5-PD8), a first floating diffusion region 630, and fifth to eighth transfer gates (TXG5-TXG8).

The first to fourth photoelectric conversion elements (PD1-PD4) may be arranged spaced apart from each other. The second pixel isolation structure 612 may be arranged between the first photoelectric conversion element (PD1) and the second photoelectric conversion element (PD2). The second pixel isolation structure 612 may be arranged between the first photoelectric conversion element (PD1) and the third photoelectric conversion element (PD3). The second pixel isolation structure 612 may be arranged between the second photoelectric conversion element (PD2) and the fourth photoelectric conversion element (PD4). The second pixel isolation structure 612 may be arranged between the third photoelectric conversion element (PD3) and the fourth photoelectric conversion element (PD4).

The fifth to eighth photoelectric conversion elements (PD5-PD8) may also be arranged spaced apart from each other. The second pixel isolation structure 612 may be arranged between adjacent photoelectric conversion elements.

The ground region 620 may be substantially identical to the ground region 320 of FIG. 4. The ground region 620 may be located at the center of the pixel.

The first floating diffusion region 630 may be arranged adjacent to each of the gates (TXG1-TXG8) of the first to eighth transfer transistors. For example, the first floating diffusion region 630 may be divided into a plurality of parts and arranged to be spaced apart from each other. The first floating diffusion regions 630 may be arranged in one-to-one correspondence with the gates (TXG1-TXG8) of the transfer transistors. When the first floating diffusion regions 630 are spaced apart from each other, the first floating diffusion regions 630 may be electrically connected to each other through a first central electrical interconnect line (not shown).

The transfer gates (TXG1-TXG8) may be arranged to overlap the photoelectric conversion element (PD1-PD8). For example, the first transfer gate (TXG1) may be arranged to overlap the first photoelectric conversion element (PD1). The fifth transfer gate (TXG5) may be arranged to overlap the fifth photoelectric conversion element (PD5). When the operating voltage is applied to each of the transfer gates (TXG1-TXG8), photocharges accumulated in the photoelectric conversion elements (PD1-PD8) overlapping the transfer gates configured to receive the operating voltage may move to the first floating diffusion region 630. For example, when the operating voltage is applied to the first transfer gate (TXG1), photocharges accumulated in the first photoelectric conversion element (PD1) configured to overlap the first transfer gate (TXG1) may move to the first floating diffusion region 630.

Functions of the first reset gate (RXG1), the first and second selection gates (SXG1, SXG2), the first to third drive gates (DXG1-DXG3), the reset drain region 641, the reset source region 642, the drive drain region 651, the drive source region 652, the selection drain region 671, and the selection source region 672 may be the same as those of FIG. 4.

The first selection gate (SXG1) may overlap the first photoelectric conversion element (PD1). The second selection gate (SXG2) may overlap the second photoelectric conversion element (PD2). The selection drain region 671 and the selection source region 672 may be arranged adjacent to the first selection gate (SXG1) and the second selection gate (SXG2). The first drive gate (DXG1) may overlap the third photoelectric conversion element (PD3). The second drive gate (DXG2) may overlap the fourth photoelectric conversion element (PD4). The third drive gate (DXG3) may overlap the fifth photoelectric conversion element (PD5). The drive drain region 651 and the drive source region 652 may be arranged adjacent to each of the first to third drive gates (DXG3). The first reset gate (RXG1) may overlap the sixth photoelectric conversion element (PD6). The reset drain region 641 and the reset source region 642 may be arranged adjacent to the first reset gate (RXG1).

The first and second DCG gates (GXG1, GXG2), the first DCG source region 681, the first DCG drain region 682, the second DCG source region 691, and the second DCG drain region 692 will be described together with the third and fourth DCG gates (GXG3, GXG4), the third DCG source region 781, the third DCG drain region 782, the fourth DCG source region 791, and the fourth DCG drain region 792.

The fourth pixel group (GPB) may include the fifth pixel (PX5) and the seventh pixel (PX7). The fifth pixel (PX5) and the seventh pixel (PX7) may be in contact with each other. Although FIG. 6 shows the seventh pixel (PX7) that vertically contacts the fifth pixel (PX5), the scope or spirit of the disclosed technology is not limited thereto, and other embodiments in which the seventh pixel (PX7) horizontally contacts the fifth pixel (PX5) are also possible.

In some embodiments, the constituent components included in the third pixel group (GPA) may have a vertically symmetrical relationship with the constituent components included in the fourth pixel group (GPB) based on a boundary between the third pixel group (GPA) and the fourth pixel group (GPB). For example, the fifth pixel (PX5) may be arranged symmetrical to the third pixel (PX3) based on the above boundary. The first pixel (PX1) may be arranged symmetrical to the seventh pixel (PX7) based on the above boundary. To reduce the lengths of the first DCG electrical interconnect line and the second DCG electrical interconnect line, the above-described symmetrical relationship may include a relationship in which the first DCG transistor (GX1) (or the second DCG transistor GX2) and the third DCG transistor (GX3) (or the fourth DCG transistor GX4), which belong to different pixel groups, are arranged to face each other with respect to the above boundary interposed therebetween.

According to the above-described symmetrical arrangement described above, the corresponding components, such as the first selection gate SXG1 overlapping the first pixel PX1 and the third selection gate SXG3 overlapping the seventh pixel PX7, may have substantially the same role and structure. Hereinafter, as representative examples, the first and second DCG gates (GXG1, GXG2), the first DCG source and drain region (681, 682), the second DCG source and drain region (691, 692) of the third pixel (PX3), as well as the third and fourth DCG gates (GXG3, GXG4), the third DCG source and drain region (781, 782), and the fourth DCG source and drain region (791, 792) of the fifth pixel (PX5) will be described in detail.

The first DCG gate (GXG1) may overlap the seventh photoelectric conversion element (PD7). A first DCG source region 681 and a first DCG drain region 682 may be arranged at both ends of the first DCG gate (GXG1). The first DCG source region 681 may be electrically connected to the first floating diffusion region 630 through the first central electrical interconnect line. The first DCG gate (GXG1) may be arranged closer to either the fifth pixel (PX5) or the boundary with respect to the center of the third pixel (PX3). Furthermore, the first DCG gate (GXG1) may be arranged closer to the ninth photoelectric conversion element (PD9) from the center of the seventh photoelectric conversion element (PD7).

The second DCG gate (GXG2) may overlap the eighth photoelectric conversion element (PD8). A second DCG source region 691 and a second DCG drain region 692 may be arranged at both ends of the second DCG gate (GXG2). The second DCG source region 691 may be electrically connected to the first DCG drain region 682 through a third DCG electrical interconnect line. The second DCG gate (GXG2) may be arranged closer to the fifth pixel (PX5) or the boundary with respect to the center of the third pixel (PX3). Furthermore, the second DCG gate (GXG2) may be arranged closer to the tenth photoelectric conversion element (PD10) from the center of the eighth photoelectric conversion element (PD8).

The third DCG gate (GXG3) may overlap the ninth photoelectric conversion element (PD9). A third DCG source region 781 and a third DCG drain region 782 may be arranged at both ends of the third DCG gate (GXG3). The third DCG source region 781 may be electrically connected to the second floating diffusion region 730 through the second central electrical interconnect line. The third DCG drain region 782 may be electrically connected to the first DCG drain region 682 through the first DCG electrical interconnect line. The third DCG gate (GXG3) may be arranged at a position corresponding to a vertically symmetrical relationship with the first DCG gate (GXG1) based on the boundary between the third pixel group (GPA) and the fourth pixel group (GPB). The third DCG gate (GXG3) may be arranged closer to the third pixel (PX3) or the boundary with respect to the center of the fifth pixel (PX5). Furthermore, the third DCG gate (GXG3) may be arranged closer to the seventh photoelectric conversion element (PD7) from the center of the ninth photoelectric conversion element (PD9).

The fourth DCG gate (GXG4) may overlap the tenth photoelectric conversion element (PD10). A fourth DCG source region 791 and a fourth DCG drain region 792 may be arranged at both ends of the fourth DCG gate (GXG4). The fourth DCG source region 791 may be electrically connected to the third DCG grain region 782 through the fourth DCG electrical interconnect line. The fourth DCG drain region 792 may be electrically connected to the second DCG drain region 692 through the second DCG electrical interconnect line. The fourth DCG gate (GXG4) may be arranged at a position corresponding to a vertically symmetrical relationship with the second DCG gate (GXG2) based on the boundary between the third pixel group (GPA) and the fourth pixel group (GPB). The fourth DCG gate (GXG4) may be arranged closer to the third pixel (PX3) or the boundary with respect to the center of the fifth pixel (PX5). Furthermore, the fourth DCG gate (GXG4) may be arranged closer to the eighth photoelectric conversion element (PD8) from the center of the tenth photoelectric conversion element (PD10).

The features of the various electrical interconnect lines described in FIGS. 3 to 5C may also be applied to the example of FIG. 6.

The pixel array 200 according to another embodiment of the disclosed technology may be repeatedly arranged with four pixels serving as a unit pixel region in the same manner as in the second pixel region 220.

As is apparent from the above description, the image sensing device based on some embodiments of the disclosed technology can achieve a higher conversion gain by reducing junction capacitance while enabling a more precisely controlled conversion gain ratio.

The embodiments of the disclosed technology may provide a variety of effects capable of being directly or indirectly recognized through the above-mentioned patent document.

Although a number of illustrative embodiments have been described, it should be understood that modifications and enhancements to the disclosed embodiments and other embodiments can be devised based on what is described and/or illustrated in this patent document.

What is claimed is:

1. An image sensing device comprising:
a pixel array of pixels for sensing incident light to capture images carried by the incident light, wherein the pixel array includes a first pixel group of pixels and a second pixel group of pixels arranged at one side of and adjacent to the first pixel group,
wherein the first pixel group includes a first pixel including first and second dual conversion gain (DCG) transistors configured to adjust a capacitance of a first floating diffusion region shared by a plurality of pixels included in the first pixel group, and
wherein the second pixel group includes a second pixel including third and fourth DCG transistors configured to adjust a capacitance of a second floating diffusion region shared by a plurality of pixels included in the second pixel group,
wherein
a gate of the first DCG transistor and a gate of the second DCG transistor are arranged such that a distance between the gates of the first and second DCG transistors and the second pixel is shorter than a distance between the second pixel and a center of the first pixel, and a gate of the third DCG transistor and a gate of the fourth DCG transistor are arranged such that a distance between the gates of the third and fourth DCG transistors and the first pixel is shorter than a distance between the first pixel and a center of the second pixel.

2. The image sensing device according to claim 1, further comprising:
a first dual conversion gain (DCG) electrical interconnect line configured to electrically connect a terminal of the first DCG transistor to a terminal of the third DCG transistor; and
a second DCG electrical interconnect line configured to electrically connect a terminal of the second DCG transistor to a terminal of the fourth DCG transistor.

3. The image sensing device according to claim 2, wherein:
the first pixel includes:
first and second photoelectric conversion elements configured to generate photocharges in response to incident light, and
the second pixel includes:
third and fourth photoelectric conversion elements configured to generate photocharges in response to the incident light.

4. The image sensing device according to claim 3, further comprising:
a pixel isolation structure disposed between the first and second photoelectric conversion elements and between the third and fourth photoelectric conversion elements.

5. The image sensing device according to claim 3, wherein
the gate of the first DCG transistor overlaps the first photoelectric conversion element,
the gate of the second DCG transistor overlaps the second photoelectric conversion element,
the gate of the third DCG transistor overlaps the third photoelectric conversion element, and
the gate of the fourth DCG transistor overlaps the fourth photoelectric conversion element.

6. The image sensing device according to claim 3, wherein:
the first pixel further includes:
a first transfer transistor configured to move the photocharges generated by the first photoelectric conversion element to the first floating diffusion region; and
a second transfer transistor configured to move the photocharges generated by the second photoelectric conversion element to the first floating diffusion region, and
the second pixel further includes:
a third transfer transistor configured to move the photocharges generated by the third photoelectric conversion element to the second floating diffusion region; and
a fourth transfer transistor configured to move the photocharges generated by the fourth photoelectric conversion element to the second floating diffusion region.

7. The image sensing device according to claim 1, wherein:
the first pixel group further includes:
a first drive transistor configured to amplify an electrical signal corresponding to photocharges stored in the first floating diffusion region, and
the second pixel group further includes:
a second drive transistor configured to amplify an electrical signal corresponding to photocharges stored in the second floating diffusion region.

8. The image sensing device according to claim 7, wherein:
the first pixel group further includes:
a first selection transistor configured to selectively output an electrical signal amplified by the first drive transistor, and
the second pixel group further includes:
a second selection transistor configured to selectively output an electrical signal amplified by the second drive transistor.

9. The image sensing device according to claim 1, wherein:
the first pixel group includes:
a first reset transistor configured to reset the first floating diffusion region, and
the second pixel group includes:
a second reset transistor configured to reset the second floating diffusion region.

10. The image sensing device according to claim 1, further comprising:
a third dual conversion gain (DCG) electrical interconnect line configured to electrically connect a terminal of the first DCG transistor to a terminal of the second DCG transistor; and
a fourth DCG electrical interconnect line configured to electrically connect a terminal of the third DCG transistor to a terminal of the fourth DCG transistor.

11. The image sensing device according to claim 1, wherein:
the first floating diffusion region is electrically connected to a terminal of the first DCG transistor, and
the second floating diffusion region is electrically connected to a terminal of the third DCG transistor.

12. An image sensing device comprising:
a first pixel including first and second photoelectric conversion elements configured to generate photocharges in response to incident light;
a second pixel including third and fourth photoelectric conversion elements configured to generate photocharges in response to the incident light, the second pixel being in contact with a side surface of the first pixel;
a third pixel including fifth and sixth photoelectric conversion elements configured to generate photocharges in response to the incident light, a side surface of the third pixel being in contact with an opposite side surface of the first pixel; and
a fourth pixel including seventh and eighth photoelectric conversion elements configured to generate photocharges in response to the incident light, the fourth pixel being in contact with an opposite side surface of the third pixel,
wherein
the first pixel includes:
first and second dual conversion gain (DCG) transistors configured to adjust conversion gains of the first and second pixels and are arranged such that a distance between the first and second DCG transistors and the side surface of the third pixel is shorter than a distance between the first and second DCG transistors and the side surface of the first pixel, and
the third pixel includes:
third and fourth DCG transistors configured to adjust conversion gains of the third and fourth pixels and are arranged such that a distance between the third and fourth DCG transistors and the opposite side surface of the first pixel is shorter than a distance between the third and fourth DCG transistors and the opposite side surface of the third pixel.

13. The image sensing device according to claim 12, wherein:
one terminal of the first DCG transistor and one terminal of the third DCG transistor are electrically connected to each other, and
one terminal of the second DCG transistor and one terminal of the fourth DCG transistor are electrically connected to each other.

14. The image sensing device according to claim 13, wherein:
the first pixel includes:
a first floating diffusion region configured to store photocharges generated by the first photoelectric conversion element and the second photoelectric conversion element, and
the third pixel includes:
a second floating diffusion region configured to store photocharges generated by the fifth photoelectric conversion element and the sixth photoelectric conversion element.

15. The image sensing device according to claim 14, wherein:
another terminal of the first DCG transistor is electrically connected to the first floating diffusion region, and
another terminal of the third DCG transistor is electrically connected to the second floating diffusion region.

16. The image sensing device according to claim 14, wherein:
the one terminal of the first DCG transistor is electrically connected to another terminal of the second DCG transistor, and
the one terminal of the third DCG transistor is electrically connected to another terminal of the fourth DCG transistor.

17. The image sensing device according to claim 12, wherein:
when all of the first to fourth DCG transistors are turned off, the first and second pixels have a high conversion gain higher than a middle conversion gain,
when the first DCG transistor is turned on and the second to fourth DCG transistors are turned off, the first pixel and the second pixel have the middle conversion gain higher than a low conversion gain and lower than the high conversion gain, and
when all of the first to fourth DCG transistors are turned on, the first pixel and the second pixel have the low conversion gain lower than the high conversion gain and the middle conversion gain.

18. The image sensing device according to claim 17, wherein:
the middle conversion gain is twice the low conversion gain.

19. The image sensing device according to claim 17, wherein:
the high conversion gain is eight times the low conversion gain.

20. The image sensing device according to claim 17, wherein:
when all of the first to fourth DCG transistors are turned off, the third and fourth pixels have a high conversion gain higher than a middle conversion gain,
when the third DCG transistor is turned on and the first, second, and fourth DCG transistors are turned off, the third and fourth pixels have the middle conversion gain higher than a low conversion gain and lower than the high conversion gain, and
when all of the first to fourth DCG transistors are turned on, the third and fourth pixels have the low conversion gain lower than the high conversion gain and the middle conversion gain.
